(19) United States
(12) Patent Application Publication
(10) Pub. No.: US 2026/0016761 A1
(43) Pub. Date: Jan. 15, 2026

(54) RETICLE ENCLOSURE FOR LITHOGRAPHY SYSTEMS

(71) Applicant: Taiwan Semiconductor Manufacturing Company, Ltd., Hsinchu (TW)

(72) Inventors: Chia-Wei WANG, Hsinchu (TW); Yi-Chen LI, Hsinchu (TW)

(73) Assignee: Taiwan Semiconductor Manufacturing Company, Ltd., Hsinchu (TW)

(21) Appl. No.: 18/771,338

(22) Filed: Jul. 12, 2024

(51) Int. Cl. G03F 7/00; G03F 1/66; H01L 21/673

(52) U.S. Cl. CPC G03F 7/70741; G03F 1/66; G03F 7/70983; H01L 21/67359

(57) ABSTRACT

A reticle enclosure includes a first cover having a first outer surface and a first inner surface and a second cover having a second outer surface and a second inner surface. The first cover and the second cover are joined together. The first cover and the second cover form an internal space therebetween configured to include a reticle. A catalyst layer is disposed on the first inner surface of the first cover and a dehumidification layer is disposed on the second inner surface of the second cover.

### BACKGROUND

A lithographic apparatus projects a pattern from a patterning device (e.g., a photomask) onto a layer of radiation-sensitive material (resist) provided on the semiconductor substrate. When the photomask is present inside a mask case (pod) during transport between fabrication facilities, an elevated humidity level in the transport vehicle leads to the outgassing of volatile organic compounds (VOC) from the mask case (pod) which results in unwanted carbon deposits forming on the surfaces of the photomask.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a schematic view of an extreme ultraviolet (EUV) lithography system with a laser-produced plasma (LPP) EUV radiation source, constructed in accordance with some embodiments of the present disclosure.

FIG. 1B is a schematic view of an EUV lithography system exposure tool according to embodiments of the disclosure.

FIG. 1C illustrates a schematic pellicle assembly installed on a reticle placed in the EUV lithography system of FIG. 1A.

FIG. 2 illustrates an example of outgassing of VOCs from a mask pod and carbon deposits forming on a photomask.

FIG. 3A is a top view of an inner surface of the upper cover of a mask pod; and FIG. 3B is a top view of an inner surface of the lower cover of a mask pod, according to embodiments of the disclosure.

FIG. 3C is a top view of an inner surface of the upper cover of the mask pod of FIG. 3A with a dehumidification layer; and FIG. 3D is a top view of an inner surface of the lower cover of FIG. 3B with a catalyst layer, according to embodiments of the disclosure.

FIG. 4 is a cross-sectional view of a closed mask pod containing a photomask, according to embodiments of the disclosure.

FIG. 5 is a cross-sectional view of an opened mask pod containing a photomask, according to embodiments of the disclosure.

FIG. 6 is an isometric view of a container for housing mask pods, according to embodiments of the disclosure.

FIG. 7 is a schematic view of a transport vehicle used to transport the containers of FIG. 6, according to embodiments of the disclosure.

FIG. 8 is a schematic view of a miniaturized clean room system, according to embodiments of the disclosure.

FIG. 9 is a schematic view of a container for housing mask pods, according to embodiments of the disclosure.

FIG. 10 is a block diagram illustrating an example computing device for controlling the operation of the containers illustrated in FIGS. 6 and 9, according to some embodiments.

FIG. 11 shows a method of enclosing a reticle in a reticle enclosure according to some embodiments of the disclosure.

### DETAILED DESCRIPTION

It is to be understood that the following disclosure provides many different embodiments, or examples, for implementing different features of the present application. Specific embodiments or examples of components and arrangements are described below to simplify the present disclosure. These are, of course, merely examples and are not intended to be limiting. For example, dimensions of elements are not limited to the disclosed range or values but may depend upon process conditions and/or desired properties of the device. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact. Various features may be arbitrarily drawn in different scales for simplicity and clarity. In the accompanying drawings, some layers/features may be omitted for simplification.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. In addition, the term “made of” may mean either “comprising” or “consisting of” Further, in the following fabrication process, there may be one or more additional operations in between the described operations, and the order of operations may be changed. In the present disclosure, the phrase “at least one of A, B and C” means either one of A, B, C, A+B, A+C, B+C or A+B+C, and does not mean one from A, one from B, and one from C, unless otherwise explained.

The present disclosure generally relates to extreme ultraviolet (EUV) lithography systems and methods. Embodiments disclosed herein are directed to an improved design of a reticle (mask) pod used for storing photomasks or blank substrates during transportation. In certain embodiments, a reticle pod is provided and includes a dual coating that is designed to dehumidify the air around the reticle or photomask, as well as decompose the volatile organic compounds (VOC) generated by outgassing, thereby reducing carbon deposition on the photomask or reticle during transportation between fabrication plants.

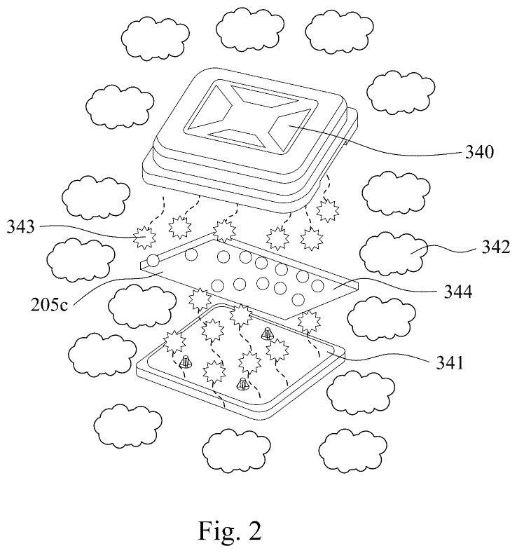

FIG. 2 provides an illustration of the outgassing of a mask pod. The mask pod includes an upper cover 340 and a lower base 341, with a reticle 205c disposed therebetween. When the upper cover 340 and the lower base 341 are sealed, the reticle 205c is secured in an internal space 351. When the plastic material of the mask pod is exposed to higher levels of humidity 342, VOCs 343 are generated by outgassing of the plastic material of the mask pod which leads to the formation of carbon deposits 344 on surfaces of the reticle 205c.

Other embodiments disclosed herein include a miniaturized clean room (mini-room) configured to store the reticle pod and maintain and monitor ideal environmental conditions during transportation. As a result, carbon deposits and damage to the reticle can be reduced during transportation. Thus, damage to the photomask (reticle) caused by carbon deposits, while contained within the reticle pod and stored in the mini-room, is reduced. Reticle mask repairs due to carbon deposits are reduced thereby resulting in increased reticle productivity.

A semiconductor chip patterned using photolithography (for example, extreme ultraviolet photolithography or EUV photolithography using 13.5 nm wavelength for patterning) uses a mask or a photomask (also called a reticle) which is contained in a standardized carrier for transfer to different positions in a clean room or different clean rooms for different processes. For example, a blank substrate is transferred in the standardized carrier using manual or robotic methods to different locations or clean rooms for cleaning and mask fabrication. The fabricated mask is also transferred inside the standardized carrier to different locations or clean rooms for photolithography processes, or storage before or after use. The mask carrier (also referred to as a mask container, a mask pod, or a mask box) includes a dual pod design with both an inner pod and an outer pod. The inner pod contacts the blank substrate or mask and includes an inner pod cover and an inner pod base. The inner pod cover and the inner pod base of the inner pod are designed to fit or join each other with high accuracy. The dual pod design is used during exposure inside fabrication facilities. It may transport the photomask (reticle) between fabrication facilities in mask pods.

Transportation of photomasks (reticles) between fabrication plants is performed by way of vehicles such as trucks. The photomasks (reticles) are transported in temperature-controlled vehicles. Air-conditioning systems provided on the vehicles increase the relative humidity environment during the transportation of the photomasks in the mask pods. In certain embodiments, the mask pods used during transportation between facilities are manufactured with plastic materials. The higher humidity level in the air-conditioned storage area (carriage) of the vehicle leads to the outgassing of volatile organic compounds (VOC) from the plastic mask pods. The presence of unacceptable levels of VOCs leads to excessive carbon deposition on the photomask or reticle while contained within the mask pod during transportation between fabrication plants.

A TVOC is a measurement of the total amount of VOCs in a given space. In certain embodiments, an acceptable TVOC measurement for an interior of the mask pod during transportation is a concentration less than 0.5 mg/n³, at a temperature of 22° C., and a relative humidity level between 20 and 40%.

Carbon deposition may occur on the photomask or blank substrate secured in the mask pod. The carbon deposits contaminate the photomask and could damage the patterns on the mask or the blank substrate or block the EUV radiation causing fabrication errors. Carbon deposits on the mask or blank substrate may severely damage the photomask or blank substrate and the damaged photomasks increase the production cost, increase manufacturing time, and lead to expensive systems for checking and removing the carbon deposits from the photomasks.

Protecting the photomask from carbon deposition may be applied to applications in semiconductor manufacturing such as extreme ultraviolet (EUV) lithography. In EUV lithography, a lithographic apparatus projects a pattern from a patterning device (e.g., a photomask) onto a layer of radiation-sensitive material (resist) provided on a semiconductor substrate. The wavelength of radiation used by the lithographic apparatus to project a pattern onto a substrate determines the minimum size of features that can be formed on that substrate. A lithographic apparatus that uses extreme ultraviolet radiation having a wavelength within the range of 1-100 nm, may be used to form smaller features on a substrate than a conventional lithographic apparatus (which may, for example, use electromagnetic radiation with a wavelength of 193 nm).

The carbon deposits on the photomask introduce defects into the pattern projected on the semiconductor substrate. It is desirable to limit the formation of the carbon deposits on the photomask. It should be noted that, although embodiments are discussed herein with reference to EUV lithography systems, embodiments are not limited in this regard. The mask pod, according to embodiments discussed herein, can be used in other types of lithography systems (e.g., deep ultraviolet (DUV) lithography systems), without departing from the scope of the disclosure.

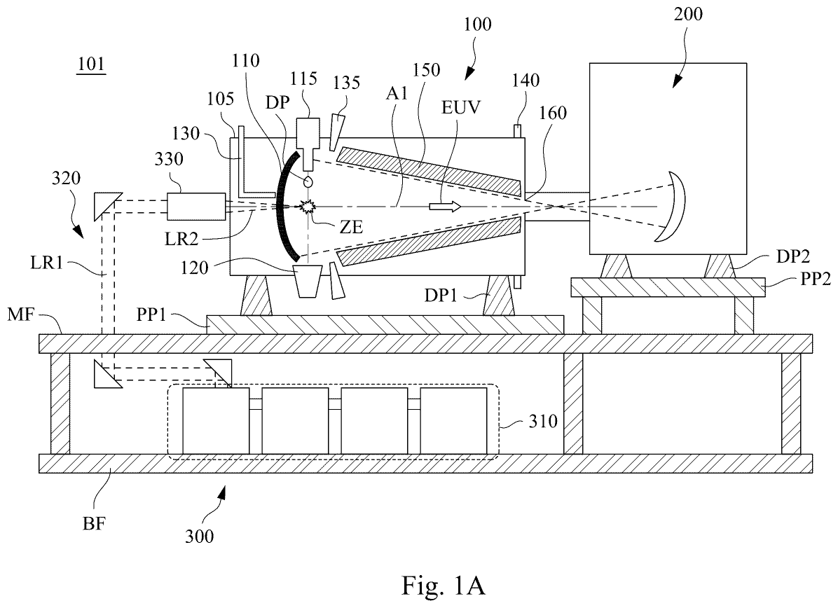

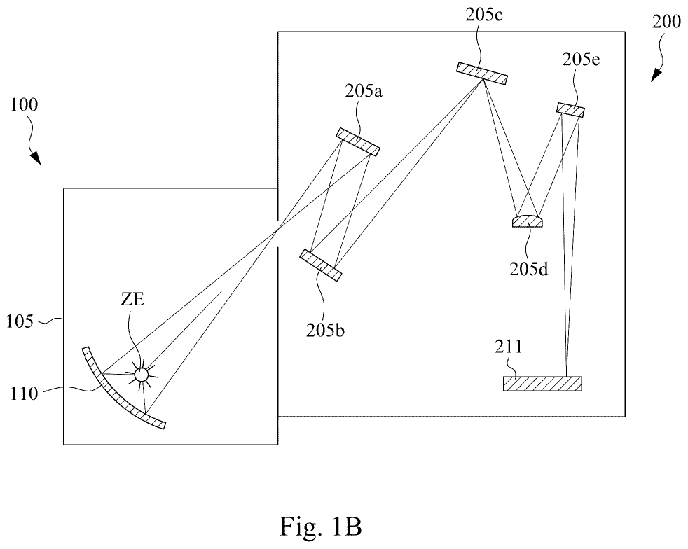

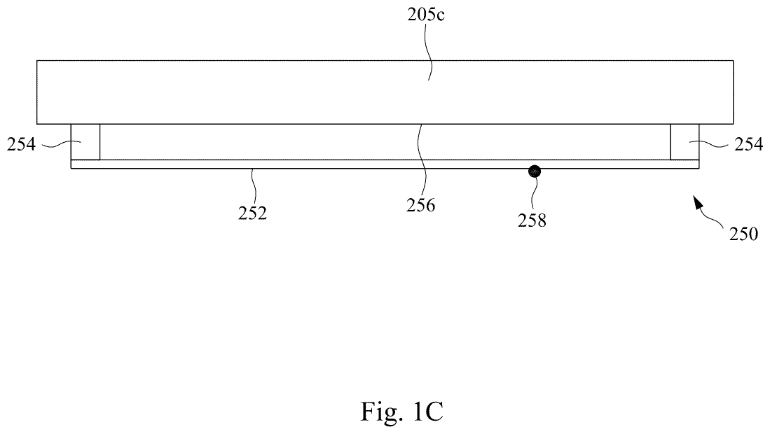

FIG. 1A is a schematic and diagrammatic view of an EUV lithography system 101. The EUV lithography system 101 includes an EUV radiation source apparatus 100 to generate EUV light, an exposure tool 200, such as a scanner, and an excitation laser source apparatus 300. As shown in FIG. 1A, in some embodiments, the EUV radiation source apparatus 100 and the exposure tool 200 are installed on a main floor MF of a clean room, while the excitation source apparatus 300 is installed in a base floor BF located under the main floor. Each of the EUV radiation source apparatus 100 and the exposure tool 200 are placed over pedestal plates PP1 and PP2 via dampers DP1 and DP2, respectively. The EUV radiation source apparatus 100 and the exposure tool 200 are coupled to each other by a coupling mechanism, which may include a focusing unit.

The EUV lithography system is designed to expose a resist layer by EUV light (or EUV radiation). The resist layer is a material sensitive to the EUV light. The EUV lithography system employs the EUV radiation source apparatus 100 to generate EUV light, such as EUV light having a wavelength ranging between about 1 nm and about 100 nm. In one example, the EUV radiation source 100 generates an EUV light with a wavelength centered at about 13.5 nm. In the present embodiment, the EUV radiation source 100 utilizes a mechanism of laser-produced plasma (LPP) to generate the EUV radiation.

The exposure tool 200 includes various reflective optic components, such as convex/concave/flat mirrors, a mask holding mechanism including a mask stage, and a wafer holding mechanism. The EUV radiation EUV generated by the EUV radiation source 100 is guided by the reflective optical components onto a mask secured on the mask stage. In some embodiments, the mask stage includes an electrostatic chuck (e-chuck) to secure the mask. Because gas molecules absorb EUV light, the lithography system for the EUV lithography patterning is maintained in a vacuum or a low-pressure environment to avoid EUV intensity loss.

FIG. 1B is a simplified schematic diagram of the exposure tool 200 according to an embodiment of the disclosure showing the exposure of photoresist-coated substrate 211 with a patterned beam of EUV light. The exposure tool 200 is an integrated circuit lithography tool such as a stepper, scanner, step and scan system, direct write system, device using a contact and/or proximity mask, etc., provided with one or more optics 205a, 205b, for example, to illuminate a patterning optic, such as a reticle 205c, with a beam of EUV light, to produce a patterned beam, and one or more reduction projection optics 205d, 205e, for projecting the patterned beam onto the substrate 211. The one or more optics 205a, 205b provide the beam of EUV light with a desired cross-sectional shape and a desired angular distribution. The reticle 205c is protected by a pellicle, which is held in place by a pellicle frame. The reticle 205c reflects and patterns the beam of EUV light.

Referring briefly to FIG. 1C, illustrated is a schematic pellicle assembly 250 installed on the reticle 205c in relative detail. The pellicle assembly 250 includes a pellicle 252 and the pellicle frame 254. The reticle 205c has a patterned surface 256. The pellicle frame 254 supports the pellicle 252 around a perimeter portion of the pellicle 252 and is removably attachable to the reticle 205c. The pellicle 252 may hold a contaminant, e.g., contamination particle 258, at a distance from the patterned surface 256 of the reticle 205c such that the contamination particle 258 is not in the focal plane of the beam of EUV radiation and is thus not imaged onto the substrate 211 (FIG. 1B).

Returning to FIG. 1B, following reflection from the reticle the patterned beam of EUV light is provided to the one or more optics 205a, 205b and is in turn projected onto the substrate 211 held by a mechanical assembly (e.g., substrate table). In some embodiments, the one or more optics 205a, 205b apply a reduction factor to the radiation beam, forming an image with features that are smaller than corresponding features on the reticle. The mechanical assembly may be provided for generating a controlled relative movement between the substrate 211 and reticle 205c.

The EUV lithography system may, for example, be used in a scan mode, wherein the chuck and the mechanical assembly (e.g., substrate table) are scanned synchronously while a pattern imparted to the radiation beam is projected onto the substrate 211 (i.e., a dynamic exposure). The velocity and direction of the substrate table relative to the chuck are determined by the demagnification and image reversal characteristics of the exposure tool 200. The patterned beam of EUV radiation that is incident upon the substrate 211 comprises a band of radiation. The band of radiation is referred to as an exposure slit. During a scanning exposure, the movement of the substrate table and the chuck is such that the exposure slit travels over an exposure field of the substrate 211. As further shown in FIG. 1B, the EUVL tool includes an EUV radiation source 100 including plasma at ZE emitting EUV light in a chamber 105 that is collected and reflected by a collector 110 along a path into the exposure tool 200 to irradiate the substrate 211.

As used herein, the term “optic” is meant to be broadly construed to include, and not necessarily be limited to, one or more components that reflect and/or transmit and/or operate on incident light, and includes, but is not limited to, one or more lenses, windows, filters, wedges, prisms, grisms, gratings, transmission fibers, etalons, diffusers, homogenizers, detectors and other instrument components, apertures, axicons and mirrors including multi-layer mirrors, near-normal incidence mirrors, grazing incidence mirrors, specular reflectors, diffuse reflectors and combinations thereof. Moreover, unless otherwise specified, the term “optic,” as used herein, is not meant to be limited to components that operate solely within one or more specific wavelength range(s) such as at the EUV output light wavelength, the irradiation laser wavelength, a wavelength suitable for metrology or any other specific wavelength.

In the present disclosure, the terms mask, photomask, and reticle are used interchangeably. In the present embodiment, the mask is a reflective mask. One exemplary structure of the mask includes a substrate with a suitable material, such as a low thermal expansion material or fused quartz. In various examples, the material includes TiO₂ doped SiO₂, or other suitable materials with low thermal expansion. The mask includes multiple reflective multiple layers deposited on the substrate. The multiple layers include a plurality of film pairs, such as molybdenum-silicon (Mo/Si) film pairs (e.g., a layer of molybdenum above or below a layer of silicon in each film pair). Alternatively, the multiple layers may include molybdenum-beryllium (Mo/Be) film pairs or other suitable materials that are configurable to highly reflect the EUV light. The mask may further include a capping layer, such as ruthenium (Ru), disposed on the ML for protection. The mask further includes an absorption layer, such as a tantalum boron nitride (TaBN) layer deposited over the multiple layers. The absorption layer is patterned to define a layer of an integrated circuit (IC). Alternatively, another reflective layer may be deposited over the multiple layers and is patterned to define a layer of an integrated circuit, thereby forming an EUV phase shift mask.

In the present embodiments, the semiconductor substrate is a semiconductor wafer, such as a silicon wafer or other type of wafer to be patterned. The semiconductor substrate is coated with a resist layer sensitive to the EUV light in the present embodiment. Various components including those described above are integrated and are operable to perform lithography exposing processes.

The lithography system may further include other modules or be integrated with (or be coupled with) other modules. As shown in FIG. 1A, the EUV radiation source 100 includes a target droplet generator 115 and an LPP collector 110, enclosed by a chamber 105. The target droplet generator 115 generates a plurality of target droplets DP. In some embodiments, the target droplets DP are tin (Sn) droplets. In some embodiments, the tin droplets each have a diameter of about 30 microns (μm). In some embodiments, the tin droplets DP are generated at a rate of about 50 droplets per second and are introduced into a zone of excitation ZE at a speed of about 70 meters per second (m/s). Other materials can also be used for the target droplets, for example, a tin containing liquid material such as eutectic alloy containing tin or lithium (Li).

The excitation laser LR2 generated by the excitation laser source apparatus 300 is a pulse laser. In some embodiments, the excitation layer includes a pre-heat laser and a main laser. The pre-heat laser pulse is used to heat (or pre-heat) the target droplet to create a low-density target plume, which is subsequently heated (or reheated) by the main laser pulse, generating increased emission of EUV light. In various embodiments, the pre-heat laser pulses have a spot size of about 100 μm or less, and the main laser pulses have a spot size of about 200-300 μm.

The laser pulses LR2 are generated by the excitation laser source 300. The laser source 300 may include a laser generator 310, laser guide optics 320, and a focusing apparatus 330. In some embodiments, the laser generator 310 includes a carbon dioxide (CO₂) or a neodymium-doped yttrium aluminum garnet (Nd:YAG) laser source. The laser light LR1 generated by the laser generator 300 is guided by the laser guide optics 320 and focused into the excitation laser LR2 by the focusing apparatus 330 and then introduced into the EUV radiation source 100.

The laser light LR2 is directed through windows (or lenses) into the zone of excitation ZE. The windows adopt a suitable material substantially transparent to the laser beams. The generation of the pulse lasers is synchronized with the generation of the target droplets. As the target droplets move through the excitation zone, the pre-pulses heat the target droplets and transform them into low-density target plumes. A delay between the pre-pulse and the main pulse is controlled to allow the target plume to form and expand to an optimal size and geometry. When the main pulse heats the target plume, a high-temperature plasma is generated. The plasma emits EUV radiation EUV, which is collected by the collector mirror 110. The collector 110 has a reflection surface that reflects and focuses the EUV radiation for the lithography exposing processes. In some embodiments, a droplet catcher 120 is installed opposite the target droplet generator 115. The droplet catcher 120 is used for catching excess target droplets. For example, some target droplets may be purposely missed by the laser pulses.

The collector 110 includes a proper coating material and shape to function as a mirror for EUV collection, reflection, and focusing. In some embodiments, the collector 110 is designed to have an ellipsoidal geometry. In some embodiments, the coating material of the collector 110 is similar to the reflective multilayer of the EUV mask. In some examples, the coating material of the collector 110 includes multiple layers (such as a plurality of Mo/Si film pairs) and may further include a capping layer (such as Ru) coated on the multiple layers to substantially reflect the EUV light. In some embodiments, the collector 110 may further include a grating structure designed to effectively scatter the laser beam directed onto the collector 110. For example, a silicon nitride layer is coated on the collector 110 and is patterned to have a grating pattern in some embodiments.

In such an EUV radiation source apparatus, the plasma caused by the laser application creates physical debris, such as ions, gases, and atoms of the droplet, as well as the desired EUV radiation. It is necessary to prevent the accumulation of material on the collector 110 and also to prevent physical debris from exiting the chamber 105 and entering the exposure tool 200.

As shown in FIG. 1A, in some embodiments, a buffer gas is supplied from a first buffer gas supply 130 through the aperture in collector 110 by which the pulse laser is delivered to the tin droplets. In some embodiments, the buffer gas is H₂, He, Ar, N₂, or another inert gas. In certain embodiments, H₂ is used as H radicals generated by ionization of the buffer gas can be used for cleaning purposes. The buffer gas can also be provided through one or more second buffer gas supplies 135 toward the collector 110 and/or around the edges of the collector 110. Further, the chamber 105 includes one or more gas outlets 140 so that the buffer gas is exhausted outside the chamber 105.

Hydrogen gas has low absorption to the EUV radiation. Hydrogen gas reaching the coating surface of the collector 110 reacts chemically with a metal of the droplet forming a hydride, e.g., metal hydride. When tin (Sn) is used as the droplet, stannane (SnH₄), which is a gaseous byproduct of the EUV generation process, is formed. The gaseous SnH₄ is then pumped out through the outlet 140. However, it is difficult to exhaust all gaseous SnH₄ from the chamber and to prevent the SnH₄ from entering the exposure tool 200.

To trap the SnH₄ or other debris, one or more debris collection mechanisms or devices 150 are employed in the chamber 105. As shown in FIG. 1A, one or more debris collection mechanisms or devices 150 are disposed along optical axis A1 between the zone of excitation ZE and an output port 160 of the EUV radiation source 100.

During the manufacture of integrated circuits using a lithographic apparatus, different reticles are used to generate different circuit patterns to be formed on different layers in the integrated circuit. Thus, during the manufacturing of different layers of the integrated circuit, the different reticles are changed. A rapid exchange device (RED), also referred to as a reticle exchange device, is used to efficiently change reticles during the lithography process.

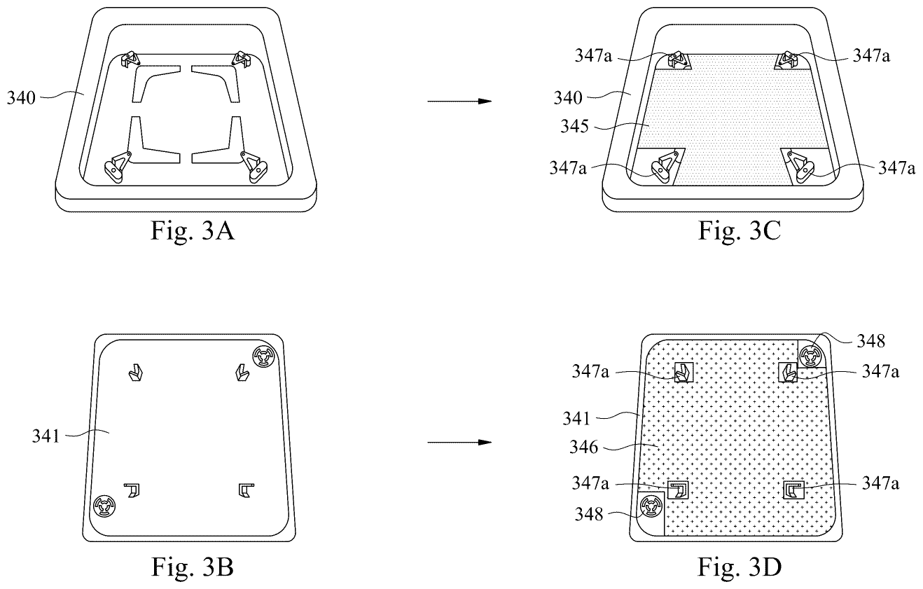

FIGS. 3A and 3B show the reticle pod including an upper cover 340 and lower base 341. FIG. 3A shows an inside surface of the upper cover 340 and FIG. 3B shows an inside surface of the lower base 341 which directly holds the reticle 205c with restraining mechanisms or supports 347a (FIGS. 3C and 3D) disposed on the upper cover 340 and lower base 341. In certain embodiments, purge valves 348 are positioned on the lower base 341 (FIG. 3D).

In certain embodiments, materials used for the mask pods include one or more plastic materials. In some embodiments, low-outgassing resin materials are used including thermoplastic polymers, such as polyether ether ketone (PEEK) and polyamide-imide. Other plastic materials such as one or more of polyvinyl chloride, polycarbonate, polypropylene, polytetrafluoroethylene, and polyethylene may be used as materials for the mask pod.

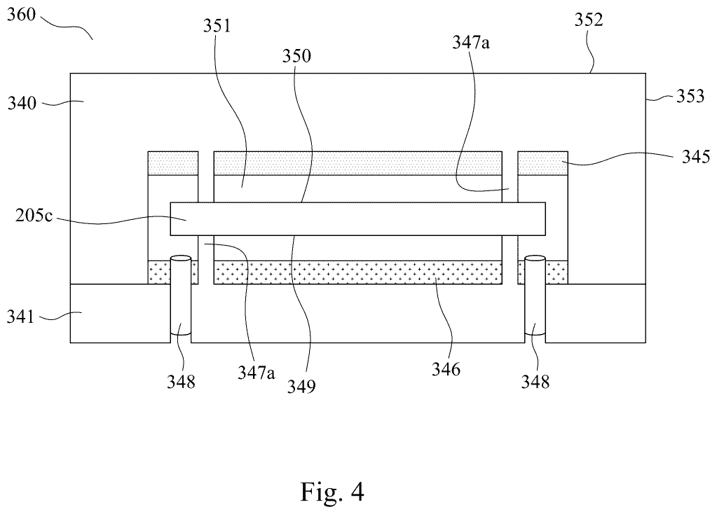

FIGS. 3A and 3B show the reticle pod before application of the dual coating shown in FIGS. 3C and 3D. In certain embodiments, a dehumidification layer 345 is applied as the first coating of the dual coating, as shown in FIG. 3C. In some embodiments, the dehumidification layer 345 is applied to an inner surface of the upper cover 340, as shown in FIG. 3C. In certain embodiments, the dehumidification layer 345 extends horizontally along an inner surface of the upper pod cover (FIG. 4), as well as on the vertical inner side surface of the side portion 353 (not shown). In certain embodiments, the dehumidification layer 345 has a thickness in a range of 5 mm to 25 mm at a pin height of 40 mm. In other embodiments, a catalyst layer 346 is applied to an inner surface of the lower base 341, as shown in FIG. 3D. The combination of the dehumidification layer 345 and catalyst layer 346 is referred to herein as the dual coating. In certain embodiments, the location of the dual coating can be reversed such that the catalyst layer 346 is located on the upper cover 340 and the dehumidification layer 345 is located on the lower base 341.

In certain embodiments, materials for the dehumidification layer 345 include a desiccant, such as silicon dioxide (SiO₂) or silica. A desiccant is a substance or material that absorbs and/or adsorbs moisture from its surroundings. In certain embodiments, the dehumidification layer 345 includes a material with adsorption properties and the ability to attract moisture and hold the moisture onto its surface thus reducing relative humidity (i.e., the amount of water moisture/vapor in the air). In some embodiments, silica gel is used as the desiccant material, but other desiccant chemicals can be used for the dehumidification layer 345. In certain embodiments, silica gel is dispersed in a polymer, and a film is produced that absorbs and/or absorbs water vapor. In certain embodiments, a desiccant film made of low-density polyethylene with dispersed silica gel is used as the dehumidification layer 345. In some embodiments, the silica gel is applied to the inner surface of the mask pod and secured to the surface of the mask pod by way of an adhesive. In other embodiments, a humidity indicator is included in the silica gel to show, by color changes, the degree of water saturation of the desiccant. In certain embodiments, an indicator such as cobalt chloride (CoCl₂) is used. Anhydrous cobalt chloride is blue in color. However, when the cobalt chloride bonds with water molecules, (e.g., CoCl₂·2H₂O), it turns purple in color. Further hydration results in the pink hexaaquacobalt(II) chloride complex [Co(H₂O)₆]Cl₂. This visual cue allows operators or engineers to gauge the saturation level of the desiccant material.

In certain embodiments, catalyst layer 346 comprises a catalyst material used for the oxidation of VOCs and includes noble metals and non-noble metals. Noble-metal-based catalysts and metal-oxide-based catalysts are known for their effectiveness with low-temperature VOC oxidation and high oxidation efficiency. In some embodiments, catalysts employed for VOC oxidation, are divided into two groups, those based on supported metals and those based on metal oxides. In certain embodiments, the former include platinum, palladium, and gold-based catalysts. Noble metal-based catalysts include platinum (Pt), palladium (Pd), silver (Ag), and Gold (Au). Non-noble metal-based catalysts include manganese (Mn), cobalt (Co), cerium (Ce), and copper (Cu). In certain embodiments, the metal catalyst attracts gaseous VOCs to the surface of the catalyst and decomposes the VOCs into carbon dioxide (CO₂) and water (H₂O) by way of a catalytic oxidation reaction. In some embodiments, a catalytic oxidation reaction for decomposing VOCs, converts the carbon-containing VOCs into CO₂ and H₂O without the generation of other harmful substances. In certain embodiments, the catalyst layer 346 has a thickness in a range of about 5 mm to 25 mm at a pin height of 40 mm.

As illustrated in FIG. 4, the reticle 205c is stored in the mask pod 360. The mask pod 360 includes an upper cover 340 and a lower base 341. In certain embodiments, the reticle 205c is stored face down in the mask pod 360. More specifically, the printed or patterned surface 349 (also referred to as the front face) of reticle 205c faces the catalyst layer 346 and the backside surface 350 of reticle 205c faces the dehumidification layer 345, in some embodiments. For the sake of clarity of illustration, the pellicle is not shown over the patterned surface 349. In some embodiments, a pellicle (not shown) is installed on the reticle 205c within one or more restraining mechanisms 347a. The mask pod 360 includes one or more restraining mechanisms 347a to reduce sliding or movement of the reticle 205c and thereby secure the reticle 205c in the mask pod 360. By way of example, restraining mechanisms 347a include a clamp, a groove, a pin, a fixation block, and a spring. The upper cover 340 couples to the lower base 341 to define an internal space 351 or the internal environment of the mask pod 360. The reticle 205c is located in the internal space 351 between the upper cover 340 and the lower base 341. In certain embodiments, as shown in FIG. 4, the upper cover 340 includes a generally horizontal top portion 352 and a side portion 353 extending generally vertically from the top portion 352 and forming the edge (sidewall) or the rim of the top portion 352.

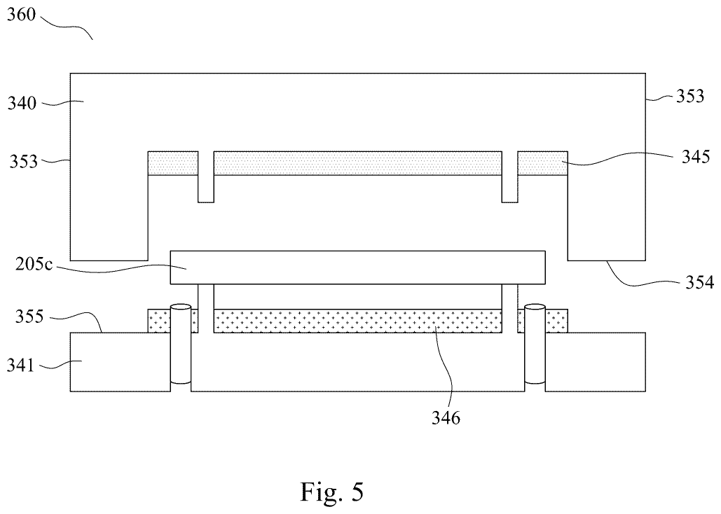

As illustrated in FIG. 5, the side portion 353 has a horizontal (or radial) width, and a surface 354 forms the lower surface (or at least a portion thereof) of the side portion 353 of the upper cover 340. The upper cover 340 and the lower base 341 are shown as separated from each other in FIG. 5. The surface 355 forms the upper surface (or at least a portion thereof) of the lower base 341. When the inner pod cover 340 is positioned over the inner pod base 346, surface 354 and surface 355 face each other (FIG. 5). When the upper cover 340 is placed on the lower base 341, the surface 354 contacts the surface 355 (FIG. 4).

In some embodiments, the one or more of the dual coating layers are removably attached to the surfaces of the upper cover 340 and the lower base 341. Thus, the dehumidification layer 345 and/or catalyst layer 346 can be easily replaced in some embodiments, for instance, in case of damage or when the dehumidification layer 345 and/or catalyst layer 346 is scheduled to be replaced. In some embodiments, the dehumidification material and/or the catalyst material are mixed with solvent, applied as a liquid mixture, and then the solvent is removed in a drying operation, leaving a solid dehumidification layer 345 and/or catalyst layer on the upper cover 340 and/or lower base 341. In some embodiments, the dehumidification layer 345 and/or catalyst layer 346 have an adhesive layer that permits the layers to be easily removed. In some embodiments, the layers 345, 346 are applied as a spin-on coat. In other embodiments, the dehumidification layer 345 and catalyst layer 346 are adhered to inside surfaces of the upper cover 340 and the lower base 341 wall by low VOC adhesive materials selected from an epoxy, acrylic, polyurethane, phenolic, rubber, PVC, silicone, and hot melt adhesive. In some embodiments, the thickness of the dehumidification layer 345 is the same or different than the thickness of catalyst layer 346. In other embodiments, dehumidification layer 345 includes one layer or multiple layers. In some embodiments, the catalyst layer 346 includes one layer or multiple layers.

As discussed above, certain embodiments of the disclosure are directed to a mask pod used during the transportation of a reticle between fabrication plants for semiconductor device fabrication. The mask pod 360 includes a dual coating on the inner surfaces of the upper cover 340 and the lower base 341. The dual coating includes a dehumidification layer 345 and a catalyst layer 346 for the decomposition of VOC.

Other embodiments, as discussed below, include a miniaturized clean room (mini-room) designed to house mask pods 360 during transportation and maintain ideal environmental conditions during transportation. As a result, carbon deposition and damage to the photomasks can be reduced during transportation. Photomask repairs are reduced thereby resulting in increased reticle productivity.

In certain embodiments, the mask pods 360 containing the photomasks 205c are moved from one fabrication facility to another. Vehicular transport, such as a truck is used to transport the mask pods 360 with the photomasks 205c contained therein. Transportation times vary depending on distances between fabrication facilities but can take up to several hours, in certain instances. The photomask 205c must be properly protected during the transportation period. The storage area of a vehicle is temperature controlled to maintain a temperature of around 20 to 22° C. Air-conditioning systems on the vehicle maintain a temperature-controlled environment during the transportation period. However, higher relative humidity levels develop as a result of the operation of the air-conditioning. The higher humidity levels exacerbate outgassing from the mask pods 360 during transportation and may lead to carbon deposits forming on surfaces of the reticles 205c, as discussed above.

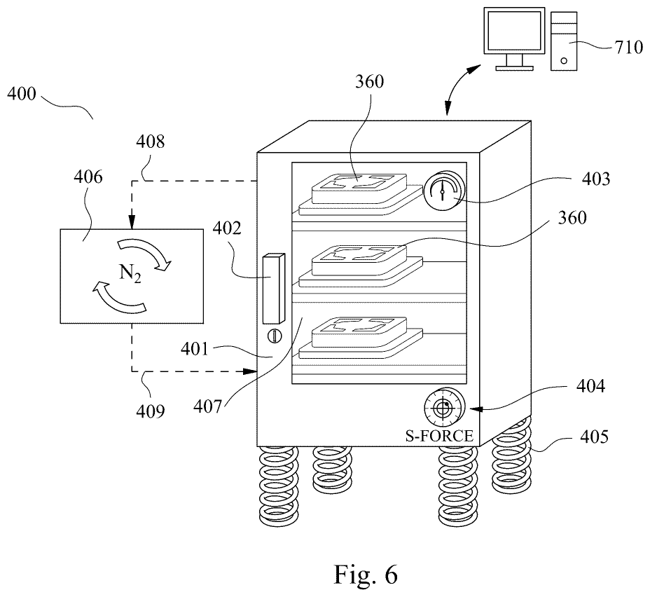

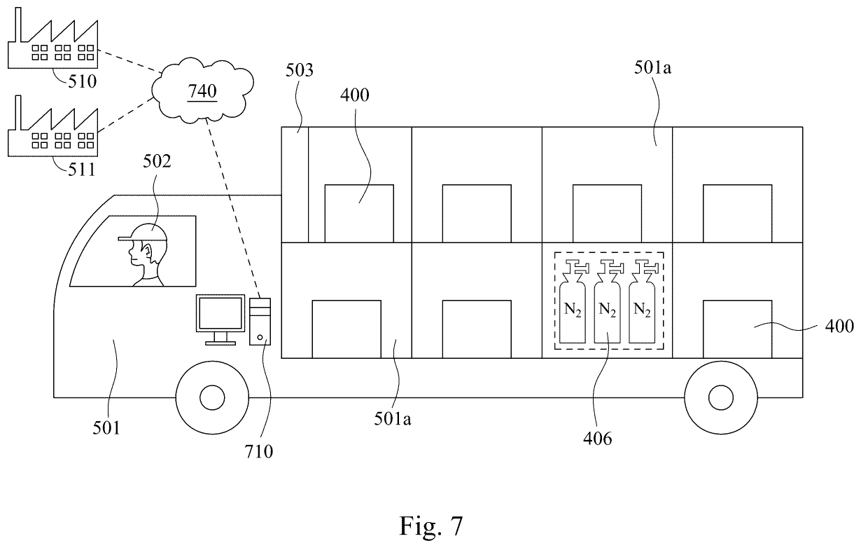

As shown in FIG. 6, in some embodiments, the mask pods 360 are placed inside a container 400. One or more of the containers 400 are loaded onto a transport vehicle, such as a truck 501 (FIG. 7). In some embodiments, each container 400 includes a door 401 with a handle 402 for opening and closing the door 401. In some embodiments, the door 401 includes a seal around the edges to maintain a proper air-tight seal while the door 401 is closed. In certain embodiments, container 400 includes a hygrometer/thermometer 403 configured to measure temperature and humidity inside container 400. In some embodiments, the hygrometer/thermometer 403 is a combined hygrometer and thermometer, but in other embodiments, two separate meters can be used to separately monitor and display the temperature and humidity levels inside container 400.

In other embodiments, one or more shock and vibration environment meters 404 are provided to measure and/or record an occurrence of shock, impact, and/or vibration above a chosen threshold during transportation of each mask pod 360. This helps to identify mask pods 360 and reticles 205c contained therein may have been mishandled during transportation. In certain embodiments, the shock and vibration environment meter(s) 404 are mechanical or electromechanical devices designed to indicate the occurrence of impacts and vibrations that are more than a given threshold. Trucks traveling on roadways can experience poor road conditions that can cause shock and vibrations during transportation. In certain embodiments, if shock and vibration environment meter 404 has not been triggered or tripped, then an inspection time for a particular container 400 can be reduced substantially as only those containers 400 that were tripped or triggered need to be inspected to ensure that no damage has occurred to the photomask 205c contained in the mask pod 360.

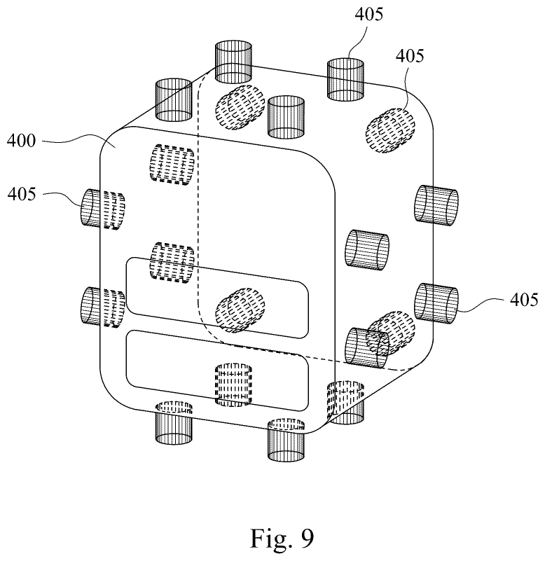

In certain embodiments, each container 400 is fitted with shock-absorbing devices 405, as shown in FIG. 6. In certain embodiments, shock-absorbing devices 405 include a spring, coil, foam, or other shock-absorbent material sufficient to absorb shock and vibration generated during transportation. As shown in FIG. 6, the shock-absorbing device 405 is positioned on the bottom surface of the container 400. However, the number and position of the shock-absorbing device 405 can vary. For example, as shown in FIG. 9, shock-absorbing devices 405 are positioned on a plurality of outer sides of the container 400 in some embodiments.

In certain embodiments, the container 400 includes an inert gas source 406 for circulating an inert gas to the interior 407 of the container 400. In some embodiments, as shown by directional arrow 408, air from the interior 407 of the container is evacuated and a fresh supply of inert gas, such as nitrogen, is introduced into the interior 407, as shown by directional arrow 409. In certain embodiments, the nitrogen source 406 includes a moisture trap to capture moisture evacuated in the air from the interior 407 of the container 400, as shown by directional arrow 408. In other embodiments, a filter is provided to remove other impurities from the air evacuated from the container 400. In some embodiments, other inert gases such as helium, argon, neon, xenon, and krypton can be used as a gas source in place of nitrogen. In certain embodiments, the purge valves 348 associated with the mask pods 360 are connected to nitrogen source 406. Air from an internal space 351 of each mask pod 360 is evacuated via the purge valves 348 from the mask pod 360 to the nitrogen source 406, in some embodiments. In some embodiments, the container 400 includes valves (not shown) attached to the container sidewalls, which allow gas to pass through the container 400 walls, with gas conduits (not shown) connecting the purge valves 348 to valves to allow inert gas flow to the mask pods 350 and evacuation of the mask pods 360. In some embodiment, purge valves are placed or fitted on vents of the container 400. In other embodiments, the nitrogen purging process replaces the existing atmosphere within the interior 407 of the container 400 and/or the internal space 351 of the mask pod 360 with nitrogen gas to remove unwanted substances and prevent damage to the photomask 205c during transportation.

As shown in FIG. 7, the container 400 can be positioned in a storage or carriage area of a vehicle, such as a truck 501. In some embodiments, the storage or carriage area 501a accommodates one or more containers 400. In certain embodiments, the nitrogen gas source is connected to each container by way of fitting, valves, and hoses to connect nitrogen source 406 to each container 400. In certain embodiments, an electronic sensor is provided that measures the humidity level of the exhaust gas as it exits the container 400. In some embodiments, each container is fitted with its own canister of inert gas supply that is attached to a respective container 400.

In some embodiments, the storage or carriage area 501a is a temperature-controlled area that includes an air-conditioning system 503 to maintain a predetermined temperature of the storage or carriage area 501a during transportation of the mask pods 360 housed in respective containers 400. In certain embodiments, an operator or driver 502 is alerted to adverse environmental conditions in the storage area and or potential damage caused to one or more of the containers 400 in the storage or carriage area 501a. In certain embodiments, alerts and/or current readings can be sent to one or more fabrication facilities for review by an operator or engineer who can contact the operator or driver 502 of the truck 501 regarding one or more alerts or equipment readings. Additional instructions to the operator or driver 502 may be provided to address the cause(s) of the alert.

In certain embodiments, the truck 501 is equipped with a computing device 710 to record and monitor readings from the container(s) 400 and other equipment in the storage or carriage area 501a. In certain embodiments, information and data collected by the computing device 710 is transmitted over a network 740 to one or more fabrication facilities 510, 511, as shown in FIG. 7. The information and data transmitted to the one or more fabrication facilities 510, 511 can be monitored for alerts in real-time. In some embodiments, operators or engineers at the one or more fabrication facilities 510, 511 are able to contact the truck operator or driver 502 with instructions for remedying the alerts and avoiding damage to the photomasks 205c. In certain embodiments, the truck 501 is a self-driving vehicle and operators or engineers are able to remotely control equipment on the truck to address and clear any alerts.

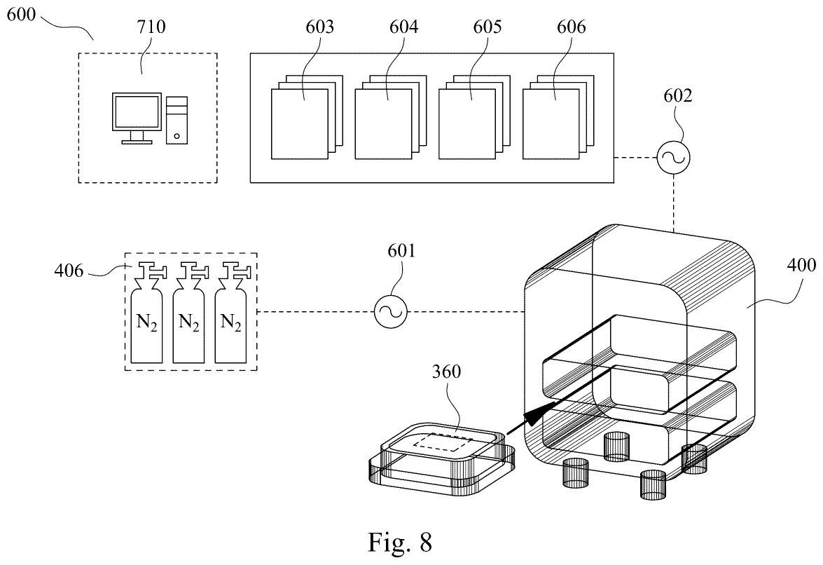

FIG. 8 is a layout of the miniaturized clean room system 600, according to some embodiments of the present disclosure. In certain embodiments, the mask pod(s) 360 is inserted into the container 400, the container door 401 is closed, and an initial supply of nitrogen gas is provided to the container from the nitrogen source 406. A gas control module 601 regulates the flow and recycling of nitrogen gas (or other inert gas) from the nitrogen source 406 to the container 400. In some embodiments, the gas control module 601 interfaces with the computing device 710, and the computing device 710 is configured to control the gas control module 601 and regulate the flow and recycling of the nitrogen gas from the nitrogen source 406 to the container 400.

In certain embodiments, the computing device 710 includes storage for storing flow rate data 606 collected from the gas control module 601. In some embodiments, a monitoring module 602 is provided to monitor data 603 received from the shock and vibration environment meter(s) 404. In some embodiments, the monitoring module 602 is configured to monitor humidity/temperature data 604 received from the hygrometer/thermometer 403. In some embodiments, the monitoring module 602 is configured to monitor data 605 associated with a lifecycle of the catalyst layer 346 contained in each mask pod 360. The catalyst layer is replaced after a predetermined time period to maintain a sufficient level of decomposition of the VOCs 343. In some embodiments, the catalyst layer 346 is replaced after 1 to 2 years of usage. In some embodiments, the monitoring module 602 monitors the lifecycle of the catalyst layer 346 and the computing device 710 generates an alert when the catalyst layer 346 is due for replacement. In other embodiments, the dehumidification layer 345 is replaced after a predetermined time period and an alert is generated by the computing device 710 advising that the dehumidification layer 345 is ready for replacement.

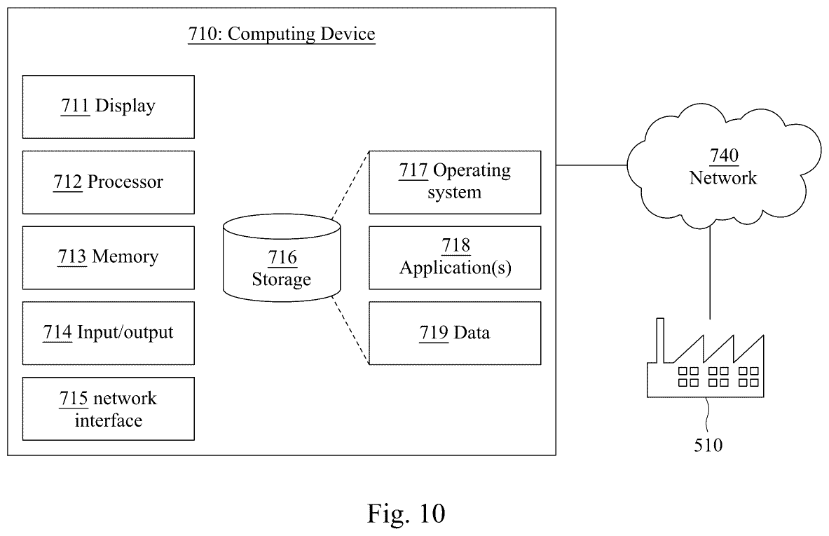

FIG. 10 is a block diagram illustrating an example computing device 710 for receiving and recording data received from gas control module 601 and/or monitoring module 602, as well as information and data from equipment in the storage area such as the air-conditioning system 503, according to some embodiments. In some embodiments, the computing device 710 is implemented using hardware or a combination of software and hardware, either in a dedicated server, integrated into another entity, or distributed across multiple entities. The computing device 710 is communicably connected to one or more remote fabrication facilities using a wireless network 740 to permit data exchange therebetween in some embodiments.

In certain embodiments, the computing device 710 is configured to calculate a level of risk for carbon deposits 344 forming on surfaces of the photomask 205c during transportation based on data collected during transportation. In certain embodiments, the computing device 710 is configured to determine a risk level associated with the formation of carbon deposits 344 based on one or more of the following: the data 603 collected from one or more of the vibration environment meter 404, the data 604 collected by the hygrometer/thermometer 403, the data 605 associated with the catalyst lifespan, and/or data 606 associated with the flow rate of the nitrogen gas. In certain embodiments, when the computing device determines that a risk for formation of carbon deposit 344 formation is high, the computing device instructs the gas control module 601 to cycle clean nitrogen into the container 400. In certain embodiments, the computing device 710 tracks the flow rate data 606 to determine a level of risk during the transportation period.

In certain embodiments of the disclosure, when the vibration environment meter 404 is tripped or triggered during transportation of the container 400 and the level of shock or vibration exceeds a threshold level, the computing device can instruct the gas control module 601 to cycle clean nitrogen air into the container 400. In other embodiments, if the lifespan of the catalyst layer 346 is nearing completion and a replacement is due, the computing device 710 instructs the gas control module 601 to cycle clean nitrogen air into the container 400. In certain embodiments, the cycling of clean nitrogen air occurs more often for a well-used catalyst layer 346 near the end of its lifespan.

In other embodiments of the present disclosure, the computing device 710 determines that a risk level for the formation of carbon deposits 344 is low when the humidity level is under 20%, and determines that the mask pod 360 is at a low-risk level for the formation of carbon deposits 344 for an estimated transportation period of at least 8 hours. In other embodiments, a medium risk level is determined when a humidity level is under 50% and an estimated transportation period between 6 to 8 hours is determined. In other embodiments, the computing device 710 determines that a high risk exists when the humidity level is under 70% and an estimated transportation period between 4 to 6 hours is determined. In other embodiments, the computing device 710 will instruct the gas control module 601 to cycle clean nitrogen air into container 400 more often when the humidity level is high to reduce the risk of carbon deposit formation and extend the transportation time period.

In certain embodiments, the computing device 710 includes a display 711, a processor 712, a memory 713, an input/output interface 714, a network interface 715, and a storage 716 storing an operating system 717, programs or applications 718, such as an application for controlling the operation of equipment associated with the container(s) 400. The processor 712 can be a general-purpose microprocessor, a microcontroller, a digital signal processor (DSP), an application specific integrated circuit (ASIC), a field-programmable gate array (FPGA), a programmable logic device (PLD), a controller, a state machine, gated logic, discrete hardware components, or any other suitable entity that can perform calculations or other manipulations of information. The storage 716 can be a random access memory (RAM), a flash memory, a read-only memory (ROM), a programmable read-only memory (PROM), an erasable PROM (EPROM), registers, a hard disk, a removable disk, a CD-ROM, a DVD, or any other suitable storage device, for storing information and instructions to be executed by processor 712. The processor 712 and storage 716 can be supplemented by, or incorporated into special purpose logic circuitry.

The network interface 715 includes networking interface cards, such as Ethernet cards and modems. In some embodiments, the input/output interface 714 is configured to connect to a plurality of devices, such as an input device and/or an output device. Example input devices include a keyboard and a pointing device, e.g., a mouse or a trackball, by which a user can provide input to the computing device 710. Other kinds of input devices are used to provide for interaction with a user as well, such as a tactile input device, visual input device, audio input device, or brain-computer interface device. For example, feedback provided to the user can be any form of sensory feedback, e.g., visual feedback, auditory feedback, or tactile feedback; and input from the user can be received in any form, including acoustic, speech, tactile, or brain wave input. Example output devices include display devices, such as an LED (light emitting diode), CRT (cathode ray tube), or LCD (liquid crystal display) screen, for displaying information to the user.

The applications 718 can include instructions which, when executed by the computing device 710 (or the processor 712 thereof), causes the computing device 710 (or the processor 712 thereof) to control modules that control the equipment associated with the container(s) 400, and perform other operations, methods, and/or processes that are explicitly or implicitly described in the present disclosure.

The data 719 can include data including default parameters used in the control operations, data that is received, for example, through the input/output interface 714 or through the network interface 715, data for displaying on the display 711, data that is transmitted to or from one or more fabrication facilities 510, 511, or data generated during operation of the computing device 710.

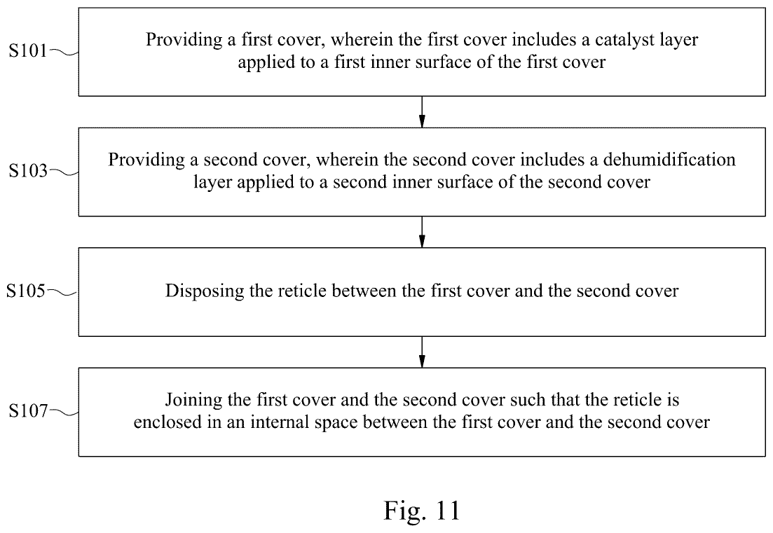

FIG. 11 shows a flowchart of a method of forming an embodiment of the present disclosure. The method includes operations S101: providing a first cover, wherein the first cover includes a catalyst layer applied to a first inner surface of the first cover, S103: providing second cover, wherein the second cover includes a dehumidification layer applied to a second inner surface of the second cover, S105: disposing the reticle between the first cover and the second cover, and S107: joining the first cover and the second cover such that the reticle is enclosed in an internal space between the first cover and the second cover. In certain embodiments, the catalyst layer is applied to the second cover and the dehumidification layer is applied to the first cover.

Embodiments of the present disclosure are directed to reducing carbon deposition on the photomask during transportation. With the present embodiments, a reticle enclosure and mini-clean room design are provided that reduce carbon deposition on the reticle during transportation. The costly repair of the reticle is reduced and productivity of the reticle and the semiconductor device manufacturing process is increased.

It will be understood that not all advantages have been necessarily discussed herein, no particular advantage is required for all embodiments or examples, and other embodiments or examples may offer different advantages.

An embodiment according to the present disclosure is a method of enclosing a reticle in a reticle enclosure. The method includes providing a first cover, wherein the first cover includes a catalyst layer applied to a first inner surface of the first cover. A second cover is provided, wherein the second cover includes a dehumidification layer applied to a second inner surface of the second cover. The reticle is disposed between the first cover and the second cover. The first cover and the second cover are joined such that the reticle is enclosed in an internal space between the first cover and the second cover. In some embodiments, the dehumidification layer includes silicon dioxide (SiO₂). In certain embodiments, the catalyst layer includes a metal. In some embodiments, the metal is selected from platinum (Pt), palladium (Pd), silver (Ag), gold (Au), manganese (Mn), cobalt (Co), cerium (Ce), or copper (Cu). In other embodiments, restraining mechanisms are provided on the first cover and the second cover for securing the reticle. In other embodiments, gas purge valves are formed in the first cover. In certain embodiments, the first cover and the second cover include a plastic material. In some embodiments, the plastic material is selected from polyether ether ketone, polyamide-imide, polyvinyl chloride, polycarbonate, polypropylene, polytetrafluoroethylene, or polyethylene. In some embodiments, the reticle includes a printed or patterned surface that faces the catalyst layer.

Another embodiment according to the present disclosure includes a reticle enclosure. The reticle enclosure includes a first cover having a first outer surface and an opposing first inner surface. A second cover includes a second outer surface and an opposing second inner surface. The first cover and the second cover contact each other such that an internal space is formed between the first cover and the second cover to include a reticle. A catalyst layer is disposed on the first inner surface of the first cover. A dehumidification layer is disposed on the second inner surface of the second cover. In some embodiments, the dehumidification layer includes silicon dioxide (SiO₂). In certain embodiments, the catalyst layer includes a metal. In some embodiments, the metal is selected from platinum (Pt), palladium (Pd), silver (Ag), gold (Au), manganese (Mn), cobalt (Co), cerium (Ce), or copper (Cu). In other embodiments, purge valves are formed in the first cover. In some embodiments, the first cover and the second cover include a plastic material. In some embodiments, the plastic material is selected from polyether ether ketone, polyamide-imide, polyvinyl chloride, polycarbonate, polypropylene, polytetrafluoroethylene, or polyethylene.

Another embodiment according to the present disclosure includes a reticle enclosure system. The system includes a reticle enclosure including a first cover including a first outer surface and a first inner surface; a second cover including a second outer surface and a second inner surface. The first cover and the second cover contact each other such that an internal space is formed between the first cover and the second cover to include a reticle. A catalyst layer is disposed on the first inner surface of the first cover. A dehumidification layer is disposed on the second inner surface of the second cover. A container is configured to house at least one reticle enclosure in an interior space of the container. A first meter is configured to measure a humidity level in the interior space of the container. A second meter is configured to measure a shock or vibration levels applied to the container. An inert gas source is configured to cycle inert gas into the interior space of the container. A controller is configured to control the inert gas source to cycle the inert gas based on at least one of the humidity level or the shock or vibration levels. In some embodiments, shock-absorbing devices are applied to one or more outer surfaces of the container. In some embodiments, the dehumidification layer comprises silicon dioxide (SiO₂). In some embodiments, the catalyst layer includes a metal.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of enclosing a reticle in a reticle enclosure, comprising:
providing a first cover, wherein the first cover includes a catalyst layer applied to a first inner surface of the first cover;
providing a second cover, wherein the second cover includes a dehumidification layer applied to a second inner surface of the second cover;
disposing the reticle between the first cover and the second cover; and
joining the first cover and the second cover such that the reticle is enclosed in an internal space between the first cover and the second cover.

2. The method according to claim 1, wherein the dehumidification layer comprises silicon dioxide (SiO₂).

3. The method according to claim 1, wherein the catalyst layer comprises a metal.

4. The method according to claim 3, wherein the metal is selected from the group consisting of platinum (Pt), palladium (Pd), silver (Ag), gold (Au), manganese (Mn), cobalt (Co), cerium (Ce), and copper (Cu).

5. The method according to claim 1, wherein restraining mechanisms are provided on the first cover and the second cover for securing the reticle.

6. The method according to claim 1, wherein gas purge valves are formed in the first cover.

7. The method according to claim 1, wherein the first cover and the second cover comprise a plastic material.

8. The method according to claim 7, wherein the plastic material is selected from the group consisting of polyether ether ketone, polyamide-imide, polyvinyl chloride, polycarbonate, polypropylene, polytetrafluoroethylene, and polyethylene.

9. The method according to claim 1, wherein the reticle includes a printed or patterned surface that faces the catalyst layer.

10. A reticle enclosure, comprising:
a first cover including a first outer surface and an opposing first inner surface;
a second cover including a second outer surface and an opposing second inner surface,
wherein the first cover and the second cover contact each other such that an internal space is formed between the first cover and the second cover to include a reticle;
a catalyst layer disposed on the first inner surface of the first cover; and
a dehumidification layer disposed on the second inner surface of the second cover.

11. The reticle enclosure of claim 10, wherein the dehumidification layer comprises silicon dioxide (SiO₂).

12. The reticle enclosure of claim 10, wherein the catalyst layer comprises a metal.

13. The reticle enclosure of claim 12, wherein the metal is selected from the group consisting of platinum (Pt), palladium (Pd), silver (Ag), gold (Au), manganese (Mn), cobalt (Co), cerium (Ce), and copper (Cu).

14. The reticle enclosure of claim 10, further comprising purge valves formed in the first cover.

15. The reticle enclosure of claim 10, wherein the first cover and the second cover comprise a plastic material.

16. The reticle enclosure of claim 15, wherein the plastic material is selected from the group consisting of polyether ether ketone, polyamide-imide, polyvinyl chloride, polycarbonate, polypropylene, polytetrafluoroethylene, and polyethylene.

17. A reticle enclosure system comprising:
a reticle enclosure including:
a first cover including a first outer surface and a first inner surface;
a second cover including a second outer surface and a second inner surface,
wherein the first cover and the second cover contact each other such that an internal space is formed between the first cover and the second cover to include a reticle,
a catalyst layer disposed on the first inner surface of the first cover; and
a dehumidification layer disposed on the second inner surface of the second cover;
a container configured to house at least one reticle enclosure in an interior space of the container;
a first meter configured to measure a humidity level in the interior space of the container;
a second meter configured to measure a shock or vibration levels applied to the container;
an inert gas source configured to cycle inert gas into the interior space of the container; and
a controller configured to control the inert gas source to cycle the inert gas based on at least one of the humidity level or the shock or vibration levels.

18. The reticle enclosure system of claim 17, further comprising shock-absorbing devices applied to one or more outer surfaces of the container.

19. The reticle enclosure system of claim 17, wherein the dehumidification layer comprises silicon dioxide (SiO₂).

20. The reticle enclosure system of claim 17, wherein the catalyst layer comprises a metal.
